(19) United States
(12) Patent Application Publication
(10) Pub. No.: US 2017/0358567 A1
(43) Pub. Date: Dec. 14, 2017

(54) TRANSIENT SUPPRESSING CIRCUIT ARRANGEMENTS

(71) Applicant: Littelfuse, Inc., Chicago, IL (US)

(72) Inventors: James Allan Peters, Wiltshire (GB); Gary Mark Bentley, Bedfordshire (GB)

(73) Assignee: Littelfuse, Inc., Chicago, IL (US)

(21) Appl. No.: 15/585,476

(22) Filed: May 3, 2017

Related U.S. Application Data
(60) Provisional application No. 62/348,242, filed on Jun. 10, 2016.

(51) Int. Cl. H01L 27/02; H01L 29/864; H01L 29/87

(52) U.S. Cl. CPC H01L 27/0255; H01L 29/87; H01L 29/864

(57) ABSTRACT

Transient suppression circuit arrangements are disclosed. In one implementation of a transient suppression circuit, at least one avalanche diode is coupled in series with a DIAC, a silicon diode for alternating current (SIDAC) device or SIDACtor.

### CROSS REFERENCE TO RELATED APPLICATIONS

This Application claims priority to U.S. Provisional Patent Application No. 62/348,242, filed Jun. 10, 2016, entitled Transient Suppressing Circuit Arrangements, and incorporated by reference herein in its entirety.

### BACKGROUND

### Field

The present invention relates generally transient suppressing circuits. More specifically, the present invention relates generally to transient suppressing circuits that may be used to mitigate against voltage transients that may occur on signal lines.

### Description of Related Art

Voltage transients are short duration voltage surges or spikes. Unsuppressed, voltage transients may damage circuits and components, possibly resulting in complete system failure.

Voltage transients may be generated from a number of different sources. For example, switching of inductive loads, such as those that occur with transformers, generators, motors, and relays, can create transients up to hundreds of volts and amps, and can last as long as hundreds of milliseconds. Such transients can negatively affect both AC and DC circuits.

Voltage transients may also be created by lightning strikes. Such lightning strikes and associated voltage transients may create disturbance on electrical and communication lines connected to electronic equipment. Another source of voltage transients is known as an automotive load dump. A load dump refers to what happens to a supply voltage in a vehicle when a load is removed. If a load is removed rapidly, such as when the battery is disconnected while the engine is running, the voltage may spike before stabilizing the damage electric components associated with the vehicle.

Circuit structures, such as a Zener diode in series with a thyristor, have been used for transient suppression. However, such circuit structures do not provide adequate transient suppression when transient voltages exceed 150 volts.

### SUMMARY

Transient suppression circuit arrangements are disclosed. In one implementation of a transient suppression circuit, at least one avalanche diode is coupled in series with a DIAC, a silicon diode for alternating current (SIDAC) device or SIDACtor. Each of the DIAC, SIDAC and SIDACtor devices is considered a threshold voltage triggered switch. In particular, such a device is considered a silicon bilateral voltage triggered switch that breaks down from high impedance to low impedance when a threshold voltage is applied. In another implementation, a plurality of avalanche diodes is coupled in series with a DIAC, SIDAC device or SIDACtor. In another implementation, at least one avalanche diode is coupled in series with a SIDACtor. In yet another implementation, a plurality of avalanche diodes is coupled in series with a SIDACtor.

### BRIEF DESCRIPTION OF THE DRAWINGS

FIG. 1 illustrates transient suppression circuit arrangement according to an embodiment.

FIG. 2 illustrates transient suppression circuit arrangement according to an embodiment.

FIGS. 3-5 illustrate breakdown characteristic of devices used in circuit arrangements.

### DETAILED DESCRIPTION

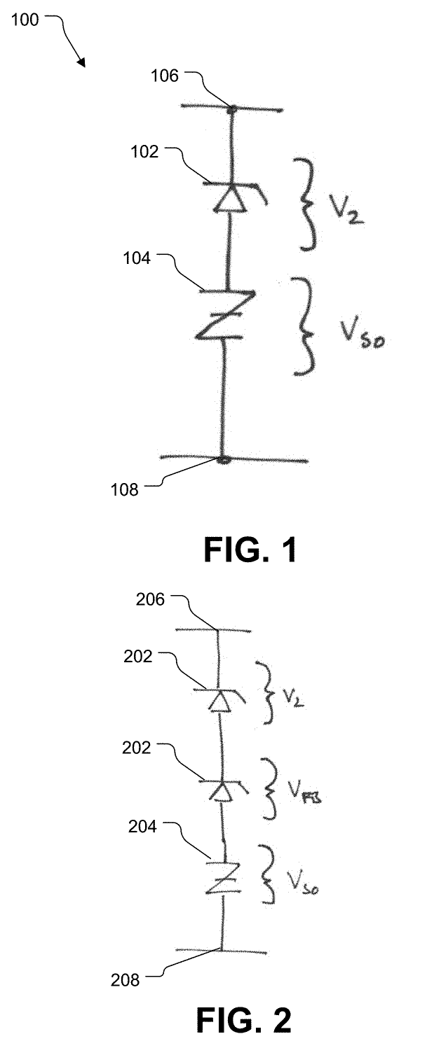

FIG. 1 illustrates transient suppression circuit 100 arrangement according to an embodiment. The transient suppression circuit 100 may include an avalanche diode 102 in series with a threshold voltage triggered switch 104, such as, a DIAC, a silicon diode for alternating current (SIDAC) device or SIDACtor. In one implementation, the threshold voltage triggered switch 104 is a SIDACtor.

The avalanche diode 102 and the SIDACtor 104 may be a coupled in series between a first input terminal 106 and a second input terminal 108. In one implementation, the first input terminal 106 or the second input terminal 108 is coupled to ground. A supply voltage may be provided to at least one of the first input terminal 106 and the second input terminal 108. The supply voltage may provide voltage to an equipment device (not illustrated) coupled to at least one of the first input terminal 106 and the second input terminal 108. The series arrangement of the avalanche diode 102 and the SIDACtor 104 is provided to protect the equipment device or the like from voltage transients that may be present at least one of the first input terminal 106 and the second input terminal 108.

In one implementation, the avalanche diode 102 has a breakdown voltage of V_{Z}, and the SIDACtor 104 has a breakdown voltage of V_{SO}. In one implementation, V_{Z} is equal to or nominally higher than a supply voltage provided at least one of the first input terminal 106 and the second input terminal 108. In one implementation, V_{Z}+V_{SO} is lower than a breakdown of voltage associated with the equipment device. In a particular implementation, V_{Z}+V_{SO} is approximately 1000-1500 volts. In another implementation, V_{Z}+V_{SO} is approximately 3000-3500 volts.

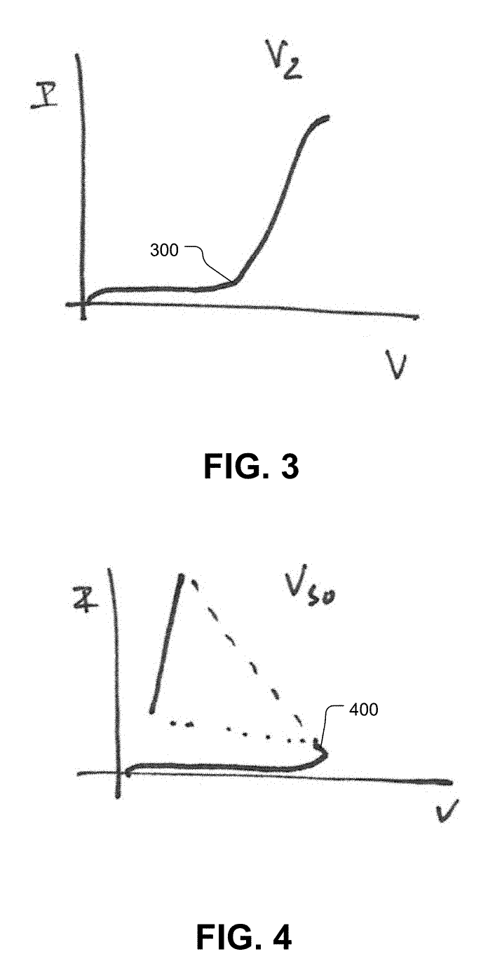

FIG. 2 illustrates transient suppression circuit 200 arrangement according to an embodiment. The transient suppression circuit 200 may include a plurality of avalanche diodes 202 in series with a threshold voltage triggered switch 204, such as, a DIAC, a silicon diode for alternating current (SIDAC) device or SIDACtor. In one implementation, the threshold voltage triggered switch 204 is a SIDACtor. More than two avalanche diodes 202 may be coupled in series with the SIDACtor 204.

The avalanche diodes 202 and the SIDACtor 204 may be a coupled in series between a first input terminal 206 and a second input terminal 208. In one implementation, the first input terminal 206 or the second input terminal 208 is coupled to ground. A supply voltage may be provided at least one of the first input terminal 206 and the second input terminal 208. The supply voltage may provide voltage to an equipment device (not illustrated) coupled to at least one of the first input terminal 206 and the second input terminal 208. The series arrangement of the avalanche diodes 202 and the SIDACtor 204 is provided to protect the equipment device or the like from voltage transients that may be present at least one of the first input terminal 206 and the second input terminal 208.

In one implementation, the avalanche diodes 202 has a breakdown voltage of V_{Z} and V_{FB}, respectively, and the SIDACtor 204 has a breakdown voltage of V_{SO}. In one implementation, V_{Z}+V_{FB}+V_{SO} is lower than a breakdown of voltage associated with the equipment device. In a particular implementation, V_{Z}+V_{FB}+V_{SO} is approximately 1000-1500 volts. In another implementation, V_{Z}+V_{FB}+V_{SO} is approximately 3000-3500 volts. In one implementation, the device 202 is a foldback (FB) (e.g., Foldbak™) diode.

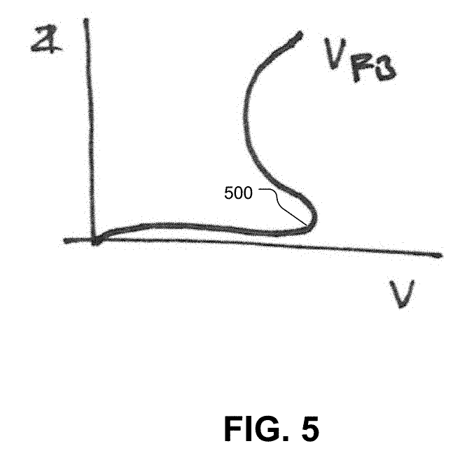

FIG. 3 illustrates the breakdown characteristic of the avalanche diodes 102 and 202. Reference numeral 300 shows the initial breakdown region associated with the avalanche diodes 102 and 202. Voltage is represented on the x-axis and current is represented on the y-axis.

FIG. 4 illustrates the breakdown characteristic of a threshold voltage triggered switchs 104 or 204, such as, a DIAC, a silicon diode for alternating current (SIDAC) device or SIDACtor. Reference numeral 400 shows the initial breakdown region associated with a threshold voltage triggered switch 104 or 204, such as, a DIAC, a silicon diode for alternating current (SIDAC) device or SIDACtor. The breakdown characteristic for V_{Z}+V_{SO} and V_{Z}+V_{FB}+V_{SO} is similar to that illustrated in FIG. 4, but the initial breakdown region will be greater than the breakdown region shown at reference 400. Voltage is represented on the x-axis and current is represented on the y-axis.

FIG. 5 illustrates the breakdown characteristic of the device 202 implemented as a foldback (e.g., foldbak) diode. Reference numeral 500 shows the initial breakdown region associated with the device 202 implemented as a FB (e.g., foldbak) diode. Voltage is represented on the x-axis and current is represented on the y-axis.

Transient suppression circuit arrangements are disclosed with reference to certain embodiments, it will be understood by those skilled in the art that various changes may be made and equivalents may be substituted without departing from the spirit and scope of the claims of the application. Other modifications may be made to adapt a particular situation or material to the teachings disclosed above without departing from the scope of the claims. Therefore, the claims should not be construed as being limited to any one of the particular embodiments disclosed, but to any embodiments that fall within the scope of the claims.

We claim:

1. An apparatus, comprising:
an avalanche diode; and
a DIAC, silicon diode for alternating current (SIDAC) or SIDACtor coupled in series with the avalanche diode.

2. The apparatus according to claim 1, wherein the avalanche diode is a plurality of avalanche diodes.

3. The apparatus according to claim 1, wherein the SIDACtor is coupled in series with the avalanche diode.

4. The apparatus according to claim 1, wherein the avalanche diode is a plurality of avalanche diodes, and the SIDACtor is coupled in series with the plurality of avalanche diodes.

5. The apparatus according to claim 1, further comprising a first input terminal and a second input terminal, the series arrangement of the DIAC, SIDAC or SIDACtor and the avalanche diode coupled between the first input terminal and the second input terminal.

6. The apparatus according to claim 5, wherein at least one of the first input terminal and the second input terminal includes a supply voltage for an equipment device coupled to the at least one of the first input terminal and the second input terminal.

7. The apparatus according to claim 5, wherein at least one of the first input terminal and the second input terminal is coupled to ground.

8. The apparatus according to claim 5, wherein the series arrangement includes the SIDACtor and avalanche diode coupled between the first input terminal and the second input terminal.

9. An apparatus, comprising:
an avalanche diode coupled in series with a foldback diode; and
a DIAC, silicon diode for alternating current (SIDAC) or SIDACtor coupled in series with the series coupled avalanche diode and foldback diode.
